(19) United States
(12) Patent Application Publication
(10) Pub. No.: US 2026/0262160 A1
(43) Pub. Date: Sep. 3, 2026

(54) FLEXIBLE CIRCUIT BOARD, DISPLAY MODULE AND DISPLAY APPARATUS

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Zheng BAO, Beijing (CN); Mingqiang WANG, Beijing (CN); Xueying HE, Beijing (CN); Yi ZHANG, Beijing (CN); Peng YANG, Beijing (CN); Lian XIANG, Beijing (CN); Gong CHEN, Beijing (CN); Yuan FANG, Beijing (CN); Jiaxiang ZHANG, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/159,745

(22) PCT Filed: Jul. 8, 2024
(86) PCT No.: PCT/CN2024/104244

§ 371 Date: Aug. 26, 2025

(30) Foreign Application Priority Data
Aug. 31, 2023 (CN) 202311116787.3

(51) Int. Cl. H05K 1/02

(52) U.S. Cl. CPC H05K 1/0218; H05K 1/0277; H05K 2201/0723; H05K 2201/10128

(57) ABSTRACT

A flexible circuit board includes a connection portion. The connection portion includes: a first circuit board layer group including a first substrate and a first line layer. The first line layer includes grounding units spaced apart along the first direction, a first line portion is arranged at a side of the grounding units, and the first line portion includes at least one first grounding line. A first insulation layer is arranged at a side of the first line layer away from the first substrate. The first insulation layer is provided with an exposed region, an orthographic projection of the exposed region on the first substrate overlaps with orthographic projections of the grounding units, and the first insulation layer exposes at least a part of the at least one first grounding line. An electromagnetic shielding layer is connected to the grounding units through the exposed region.

### CROSS-REFERENCE TO RELATED APPLICATIONS

The present disclosure is a U.S. national stage of International Application No. PCT/CN2024/104244, filed on Jul. 8, 2024, which claims priority to Chinese patent application No. 202311116787.3 filed on Aug. 31, 2023, entitled “FLEXIBLE CIRCUIT BOARD, DISPLAY MODULE AND DISPLAY DEVICE”, the entire contents of which are incorporated herein by reference in their entirety for all purposes.

### TECHNICAL FIELD

The present disclosure relates to the display technical field, and in particular to a flexible circuit board, a display module and a display device.

### BACKGROUND

In order to facilitate the assembly of a display module, a connection portion of a flexible circuit board is reversely bent. Thus, the connection portion is set and a bending region is reserved at the connection portion.

More and more functions are integrated into display devices. While ensuring a grounding effect of an electromagnetic shielding layer of the connection portion, the bending performance of the connection portion also needs to be taken into consideration.

It should be noted that the information disclosed in the above background section is only used to enhance understanding of the background of the present disclosure, and therefore may include information that does not constitute the prior art known to those of ordinary skill in this art.

### SUMMARY

The present disclosure provides a flexible circuit board, a display module and a display device.

According to an aspect of the present disclosure, there is provided a flexible circuit board, including a connection portion extending along a first direction. The connection portion includes: a first circuit board layer group, a first insulation layer and an electromagnetic shielding layer. The first circuit board layer group includes a first substrate and a first line layer. The first line layer is arranged at a side of the first substrate, the first line layer includes a plurality of grounding units spaced apart and arranged along the first direction, a first line portion is arranged at a side of the plurality of grounding units, and the first line portion includes a first grounding line. The first insulation layer is arranged at a side of the first line layer away from the first substrate. The first insulation layer is provided with an exposed region, an orthographic projection of the exposed region on the first substrate overlaps with orthographic projections of the grounding units on the first substrate, and the first insulation layer exposes at least a part of the first grounding line. The electromagnetic shielding layer is arranged at a side of the first insulation layer away from the first substrate, wherein the electromagnetic shielding layer is connected to the grounding units through the exposed region and is connected to an exposed part of the first grounding line.

According to another aspect of the present disclosure, there is provided a display module. The display module includes the flexible circuit board provided in an aspect of the present disclosure.

It is to be understood that the foregoing general description and the following detailed description are illustrative and explanatory only and are not restrictive of the present disclosure.

### BRIEF DESCRIPTION OF THE DRAWINGS

The accompanying drawings herein, which are incorporated into the description and constitute a part of the description, illustrate embodiments consistent with the present disclosure, and serve to explain the principles of the present disclosure together with the description. Obviously, the accompanying drawings described below are only some embodiments of the present disclosure, and for those of ordinary skill in this art, other accompanying drawings can be obtained based on these accompanying drawings without creative work.

FIG. 1 is a schematic diagram of a structure of a flexible circuit board involved in an embodiment of the present disclosure.

FIG. 2 is a schematic cross-sectional diagram of a connection portion of a flexible circuit board involved in an embodiment of the present disclosure when first line portions are spaced apart and arranged at both sides of a grounding structure respectively.

FIG. 3 is a schematic plan view of a first line layer involved in an embodiment of the present disclosure when first line portions are spaced apart and arranged at both sides of a grounding structure respectively.

FIG. 4 is a schematic plan view of the first line layer and a first insulation layer involved in an embodiment of the present disclosure when the first line portions are spaced apart and arranged at both sides of the grounding structure respectively.

FIG. 5 is a schematic plan view of the first line layer, the first insulation layer and an electromagnetic shielding layer involved in an embodiment of the present disclosure when the first line portions are spaced apart and arranged at both sides of the grounding structure respectively.

FIG. 6 is another schematic cross-sectional diagram of a connection portion of a flexible circuit board involved in an embodiment of the present disclosure when first line portions are spaced apart and arranged at both sides of a grounding structure.

FIG. 7 is yet another schematic cross-sectional diagram of a connection portion of a flexible circuit board involved in an embodiment of the present disclosure when first line portions are spaced apart and arranged at both sides of a grounding structure respectively.

FIG. 8 is yet another schematic cross-sectional diagram of a connection portion of a flexible printed circuit board involved in an embodiment of the present disclosure when first line portions are spaced apart and arranged at both sides of a grounding structure respectively.

FIG. 9 is a schematic cross-sectional diagram of a connection portion of a flexible circuit board involved in an embodiment of the present disclosure when each grounding unit is connected to first line portions on both sides respectively.

FIG. 10 is a schematic plan view of a first line layer involved in an embodiment of the present disclosure when each grounding unit is connected to the first line portions on both sides respectively.

FIG. 11 is a schematic plan view of the first line layer and a first insulation layer involved in an embodiment of the present disclosure when each grounding unit is connected to the first line portions on both sides respectively.

FIG. 12 is a schematic plan view of the first line layer, the first insulation layer and an electromagnetic shielding layer involved in an embodiment of the present disclosure when each grounding unit is connected to the first line portions on both sides respectively.

FIG. 13 is a schematic cross-sectional diagram of a connection portion of a flexible circuit board involved in an embodiment of the present disclosure when a first line portion and a second line portion are spaced apart and arranged at both sides of a grounding structure respectively.

FIG. 14 is a schematic plan view of a first line layer involved in an embodiment of the present disclosure when the first line portion and the second line portion are spaced apart and arranged at both sides of the grounding structure respectively.

FIG. 15 is a schematic plan view of the first line layer and a first insulation layer involved in an embodiment of the present disclosure when the first line portion and the second line portion are spaced apart and arranged at both sides of the grounding structure respectively.

FIG. 16 is a schematic plan view of the first line layer, the first insulation layer and an electromagnetic shielding layer involved in an embodiment of the present disclosure when the first line portion and the second line portion are spaced apart and arranged at both sides of the grounding structure respectively.

FIG. 17 is a schematic cross-sectional diagram of a connection portion of a flexible circuit board involved in an embodiment of the present disclosure when each grounding unit is connected to a first line portion and a second line portion on both sides respectively.

FIG. 18 is a schematic plan view of a first line layer involved in an embodiment of the present disclosure when each grounding unit is connected to the first line portion and the second line portion on both sides respectively.

FIG. 19 is a schematic plan view of the first line layer and a first insulation layer involved in an embodiment of the present disclosure when each grounding unit is connected to the first line portion and the second line portion on both sides respectively.

FIG. 20 is a schematic plan view of the first line layer, the first insulation layer and an electromagnetic shielding layer involved in an embodiment of the present disclosure when each grounding unit is connected to the first line portion and the second line portion on both sides respectively.

FIG. 21 is a schematic plan view of a first line layer and a first insulation layer involved in an embodiment of the present disclosure when first line portions are spaced apart and arranged at both sides of a grounding structure respectively.

FIG. 22 is a schematic cross-sectional diagram of a connection portion of a flexible circuit board involved in an embodiment of the present disclosure when a first circuit board layer group further includes a second line layer.

FIG. 23 is a flowchart of a process for manufacturing a flexible circuit board involved in an embodiment of the present disclosure.

FIG. 24 is a schematic diagram showing a state of a connection portion after a first conductive layer and a second conductive layer are respectively formed on two opposite sides of a first substrate.

FIG. 25 is a schematic diagram showing a state of a connection portion after a second conductive layer is patterned to form a second line layer.

FIG. 26 is a schematic diagram showing a state of a connection portion after a second substrate and a second line layer are bonded together.

FIG. 27 is a schematic diagram showing a state of a connection portion after a first via hole and a second via hole are prepared.

FIG. 28 is a schematic diagram showing a state of a connection portion after a first conductive structure is filled in a first via hole and a second conductive structure is filled in a second via hole.

FIG. 29 is a schematic diagram showing a state of a connection portion after a first line layer and a third line layer are formed.

FIG. 30 is a schematic diagram showing a state of a connection portion after a first insulation layer and a second insulation layer are formed.

### DETAILED DESCRIPTION

Example implementations will now be described more fully with reference to the accompanying drawings. However, the example implementations can be implemented in a variety of forms and should not be construed as limited to the implementations set forth herein; rather, these implementations are provided so that the present disclosure will be comprehensive and complete and fully convey the concepts of the example implementations to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “upper” and “lower” are used in this description to describe a relative relationship of a component shown in a drawing to another component, these terms are used in this description only for convenience, for example, the terms are based on direction(s) of examples described in the drawings. It can be understood that if a device in a drawing is turned upside down, a component described as an “upper” component will become a “lower” component. When a structure is “on” another structure, it may mean that the structure is formed integrally on another structure, or that the structure is “directly” disposed on another structure, or that the structure is “indirectly” disposed on another structure through other structure(s).

The terms “one”, “a/an”, “the”, “said” and “at least one” are used to indicate the presence of one or more elements/components/etc. The terms “comprising/including” and “having” are used to express an open-ended inclusive meaning and mean that additional elements/components/etc. may exist in addition to the listed elements/components/etc. The terms “first”, “second” and “third” etc. are used merely as markers and are not intended to limit the quantity of associated objects.

### Description of Reference Numerals

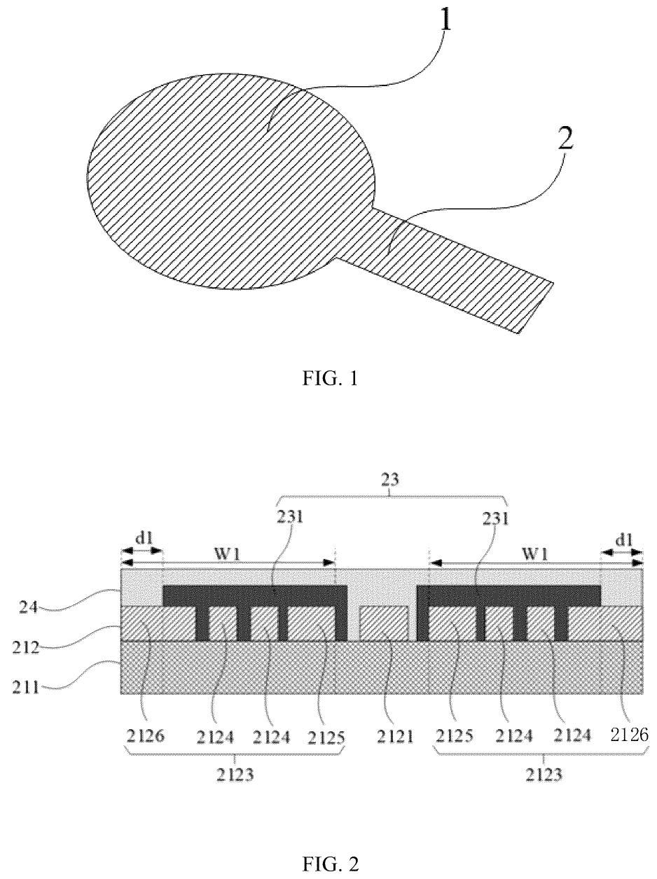

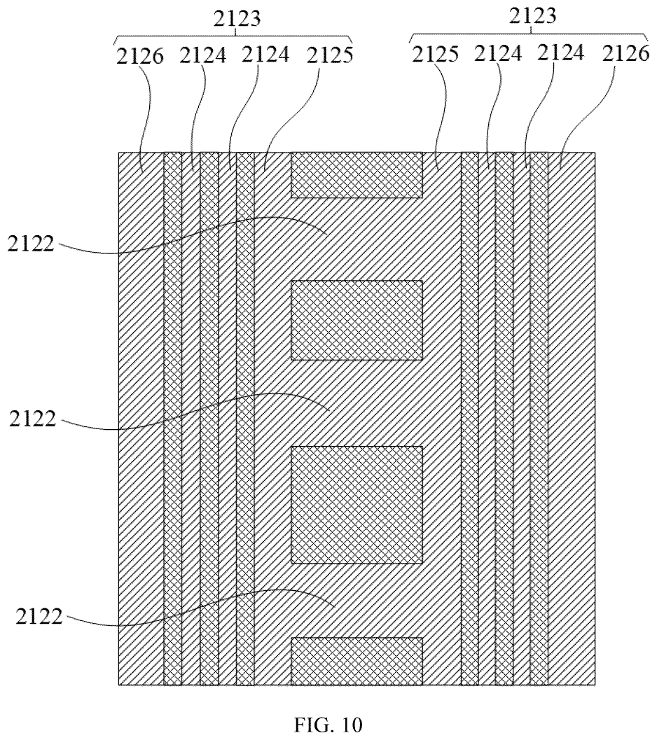

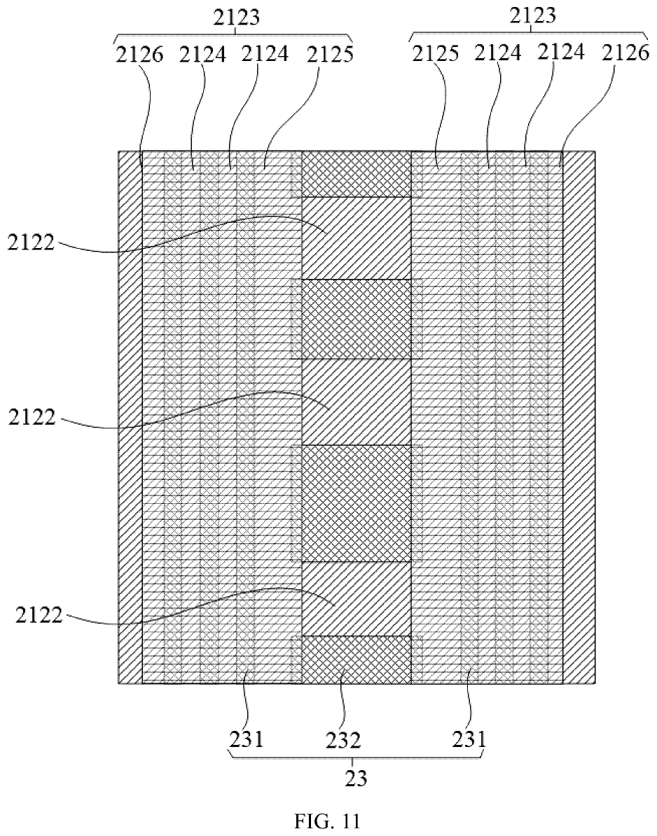

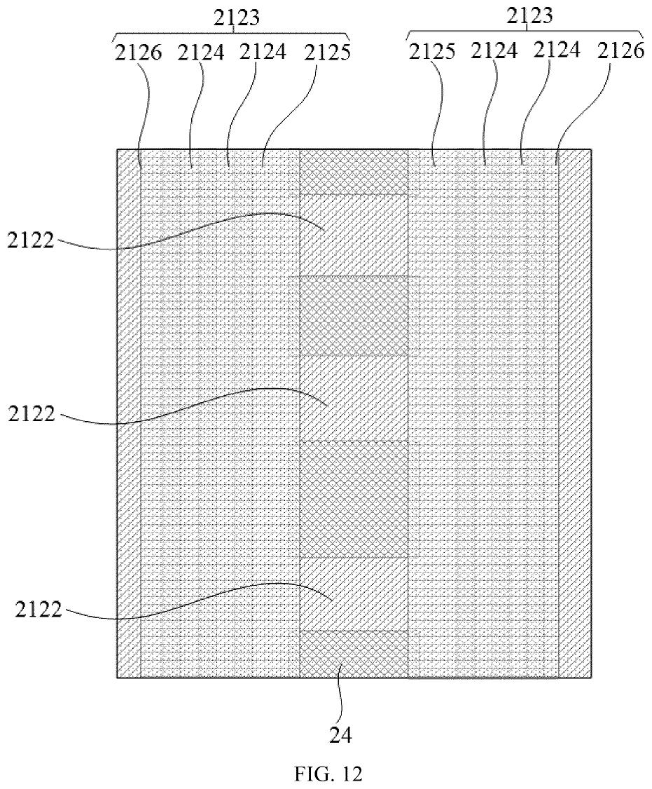

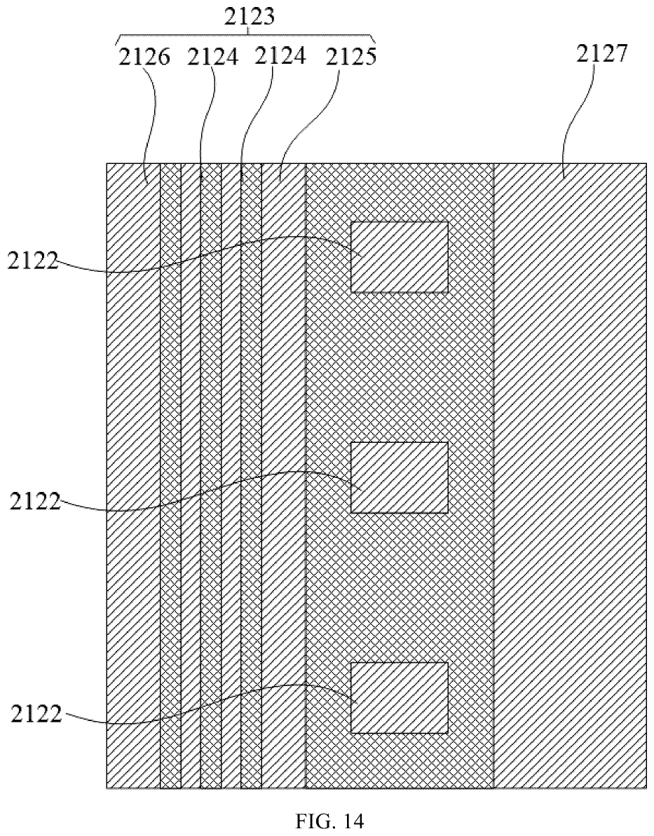

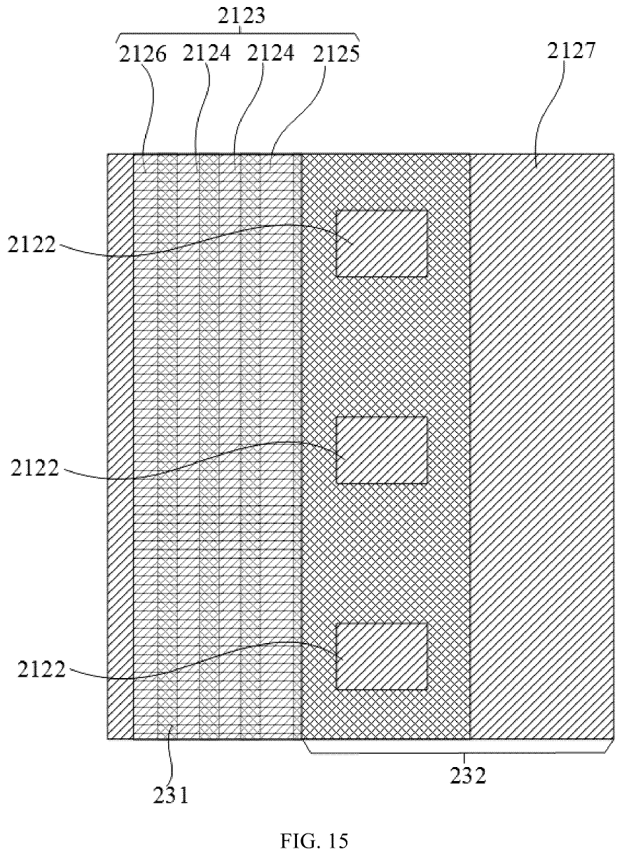

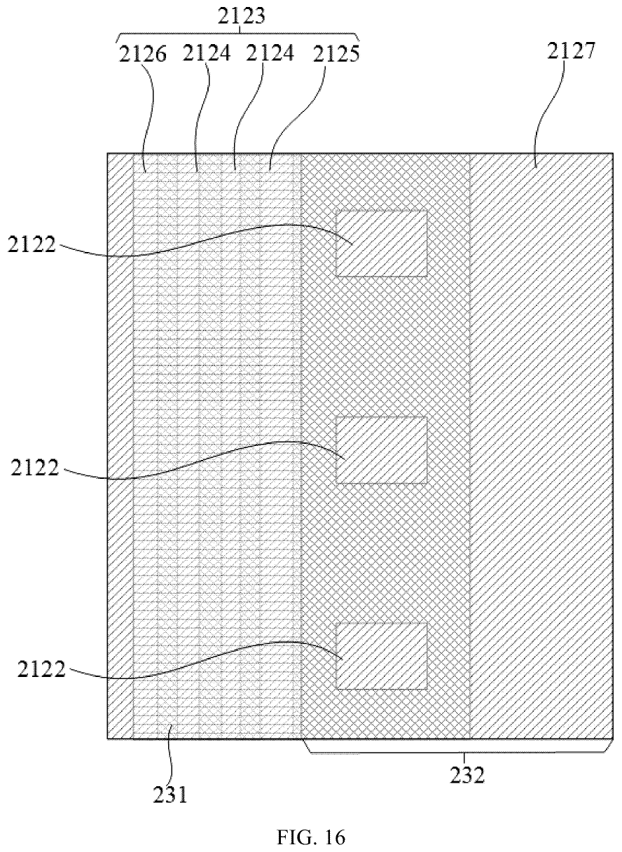

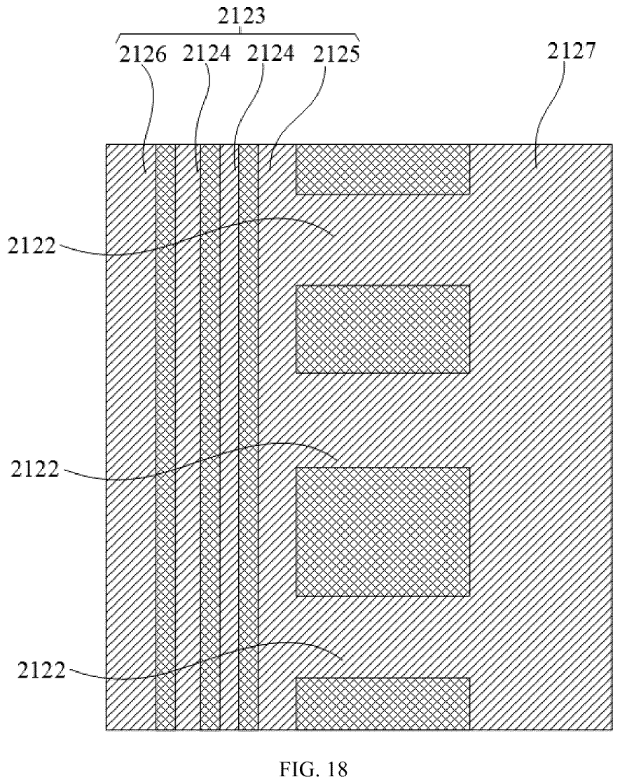

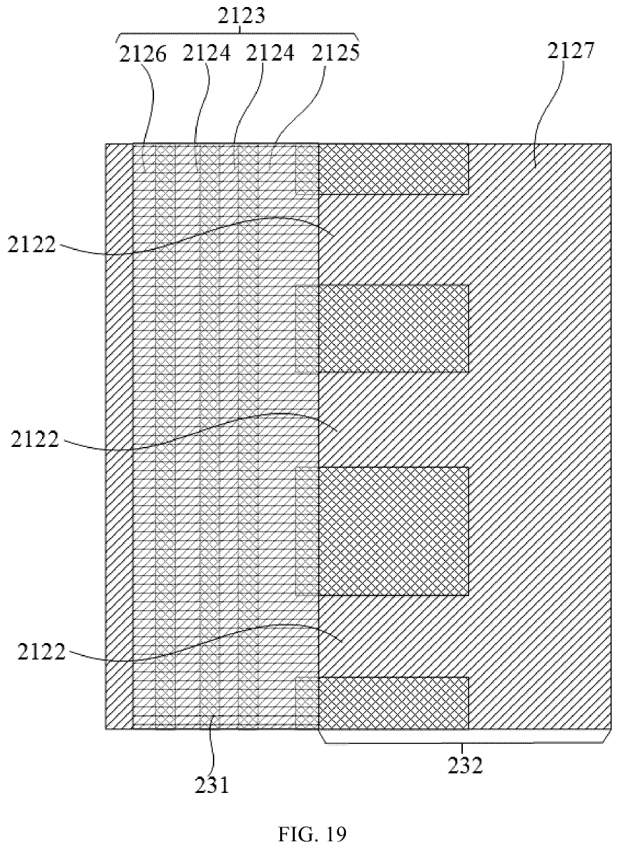

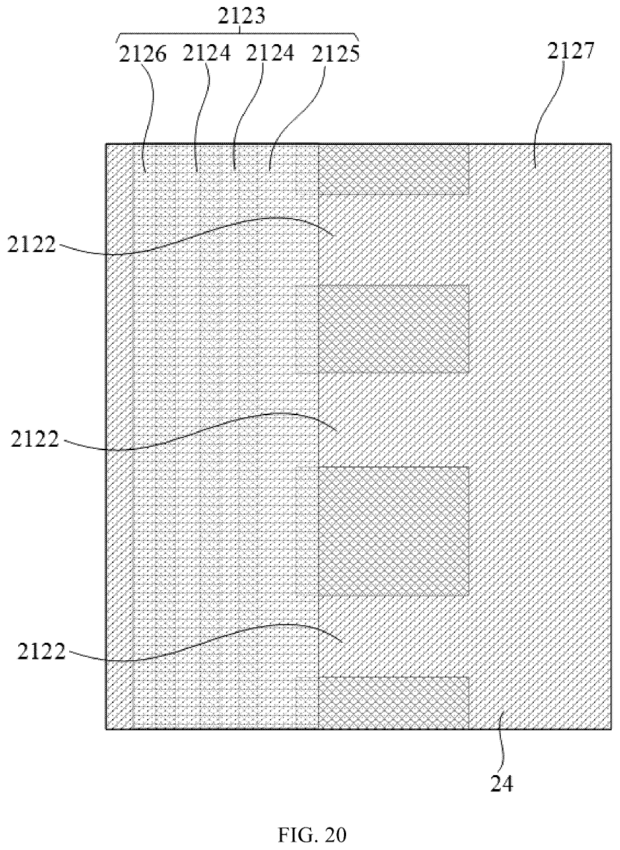

1: main body; 2: connecting portion; 21: second circuit board layer group; 211: first substrate; 212: first line layer; 2121: grounding structure; 2122: grounding unit; 2123: first line portion; 2124: first signal line; 2125: first grounding sub-line; 2126: second grounding sub-line; 2127: second line portion; 213: second line layer; 2131: second signal line; 2132: third grounding sub-line; 2133: fourth grounding sub-line; 2134: third grounding portion; 2135: fourth grounding portion; 22: first circuit board layer group; 221: second substrate: 222: third line layer: 23: first insulation layer; 231: first insulation portion; 232: exposed region; 2321: opening; 24: electromagnetic shielding layer; 25: adhesive layer; 26: first conductive structure; 27: second conductive structure; 28: second insulation layer; 291: first via hole; 292: second via hole; 3: first conductive layer; 4: second conductive layer; 5: third conductive layer. An implementation of the present disclosure provides a flexible circuit board. As shown in FIGS. 1 to 22, the flexible circuit board includes a connection portion 2 extending along a first direction. The connection portion 2 includes a first circuit board layer group 22, a first insulation layer 23 and an electromagnetic shielding layer 24. The first circuit board layer group 22 includes a first substrate 211 and a first line layer 212. The first line layer 212 is arranged at a side of the first substrate 211. The first line layer 212 includes a plurality of grounding units 2122 spaced apart and arranged along the first direction, and a first line portion 2123 is arranged at a side of the plurality of grounding units 2122. The first line portion 2123 includes a first grounding line. The first insulation layer 23 is arranged at a side of the first line layer 212 away from the first substrate 211. The first insulation layer 23 is provided with an exposed region 232. An orthographic projection of the exposed region 232 on the first substrate 211 overlaps with the orthographic projections of the grounding units 2122 on the first substrate 211. The first insulation layer 23 exposes at least part of the first grounding line. The electromagnetic shielding layer 24 is arranged at a side of the first insulation layer 23 away from the first substrate 211. The electromagnetic shielding layer 24 is connected to the grounding units 2122 through the exposed region 232, and is connected to the exposed part of the first grounding line.

The connection portion 2 of the flexible circuit board includes the first line layer 212, the first insulation layer 23 and the electromagnetic shielding layer 24 which are stacked. The first line layer 212 includes a plurality of grounding units 2122. In the first line layer 212, the parts between the grounding units 2122 are cut out, thus reducing the thickness of the connection portion 2 in this region and reducing the bending rebound force of the connection portion 2. The first insulation layer 23 is provided with the exposed region 232, and the orthographic projection of the exposed region 232 on the first substrate 211 overlaps with the orthographic projections of the grounding units 2122 on the first substrate 211. The electromagnetic shielding layer 24 is connected to the grounding units 2122 through the exposed region 232, which can ensure the grounding effect of the electromagnetic shielding layer 24. Therefore, the flexible circuit board can take into account the bending performance of the connection portion 2 while ensuring the grounding effect of the electromagnetic shielding layer 24 of the connection portion 2.

The flexible circuit board involved in the implementations of the present disclosure will be described in detail below with reference to specific embodiments.

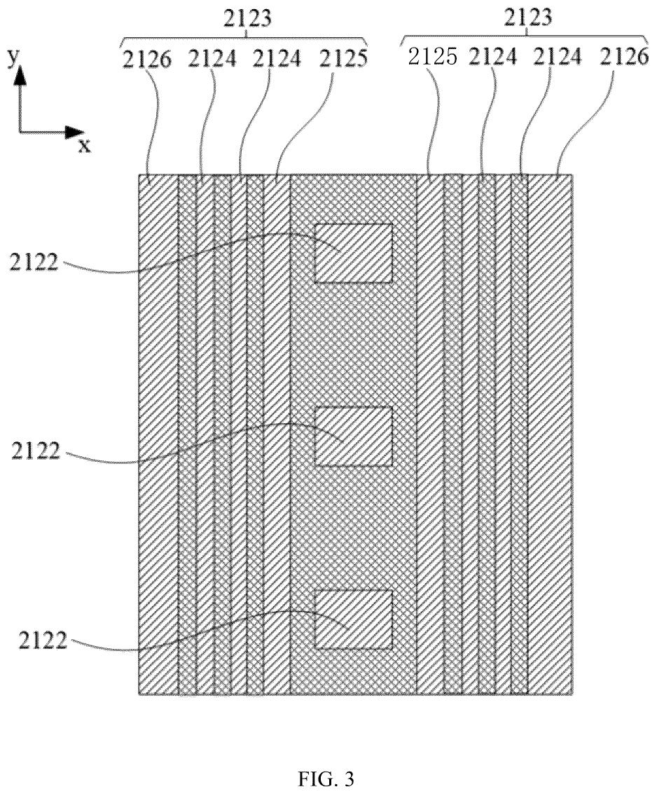

As shown in FIG. 1, the flexible circuit board includes a main body 1 and a connection portion 2. An end of the connection portion 2 is connected to an edge of the main body 1, and the other end of the connection portion 2 is connected to a main board of a display device. The connection portion 2 extends along a first direction. As shown in FIG. 2 and FIG. 3, the connection portion 2 includes a first circuit board layer group 22. The first circuit board layer group 22 includes a first substrate 211 and a first line layer 212. The first line layer 212 is arranged at a side of the first substrate 211. The first line layer 212 includes a grounding structure 2121. First line portions 2123 are provided at two sides of the grounding structure 2121 along the second direction. The first line portions 2123 are used to connect with a binding portion of the display panel. The widths W1 of the first line portions 2123 at both sides are the same, and the distances between the two first line portions 2123 and the plurality of grounding units 2122 are equal, so as to avoid peeling between layers due to uneven force on the connection portion 2 when bending.

It should be noted that the second direction is perpendicular to the first direction. The first direction is the x direction shown in FIG. 3, and the second direction is the y direction shown in FIG. 3.

A first line portion 2123 includes two first signal lines 2124, and a first grounding line is respectively provided at both sides of the two first signal lines 2124. The signals of the two first signal lines 2124 of the first line portion 2123 are shielded by the first grounding lines to prevent the signals of two first line portions 2123 from interfering with each other. The two first grounding lines include a first grounding sub-line 2125 and a second grounding sub-line 2126. The first grounding sub-line 2125 is located between the plurality of grounding units 2122 and a first signal line 2124, and the second grounding sub-line 2126 is located between a first signal line 2124 and an edge of the first substrate 211.

The grounding structure 2121 may include a plurality of grounding units 2122 which are spaced apart and arranged along a first direction. Two first grounding sub-lines 2125 are spaced apart and arranged at both sides of the plurality of grounding units 2122. In the first line layer 212, parts between two adjacent grounding units 2122 and parts between the grounding units 2122 and the two first grounding sub-lines 2125 are hollowed out. Two first signal lines 2124 are sequentially arranged at a side of the first grounding sub-line 2125 away from the grounding units 2122, and a second grounding sub-line 2126 is arranged at the outer side of the first signal line 2124 farthest from the plurality of grounding units 2122. The two first grounding sub-lines 2125 are equidistant from the plurality of grounding units 2122.

It can be understood that a grounding unit 2122 is an island structure in the first line layer 212, and the part of the first line layer 212 located around each grounding unit 2122 is hollowed out. In order to facilitate the processing of a mask pattern and reduce the cost of patterning the first line layer 212 and forming the grounding unit 2122, in this embodiment, the shape of the grounding unit 2122 is set to a regular shape, such as a rectangle. Of course, the grounding unit 2122 may also be set to other shape(s) such as a circle, a pentagon, a triangle, etc., which are not listed here one by one. Furthermore, the grounding structure 2121 may also set as follows: the spacing between any adjacent grounding units 2122 is equal.

The two first signal lines 2124, the first grounding sub-line 2125 and the second grounding sub-line 2126 all extend along the first direction. Along the first direction, the widths of various parts of the first signal line 2124 are equal, the widths of various parts of the first grounding sub-line 2125 are equal, and the widths of various parts of the second grounding sub-line 2126 are equal. The width of the first grounding sub-line 2125 and the width of the second grounding sub-line 2126 are greater than the width of the first signal line 2124, which can achieve a better grounding effect.

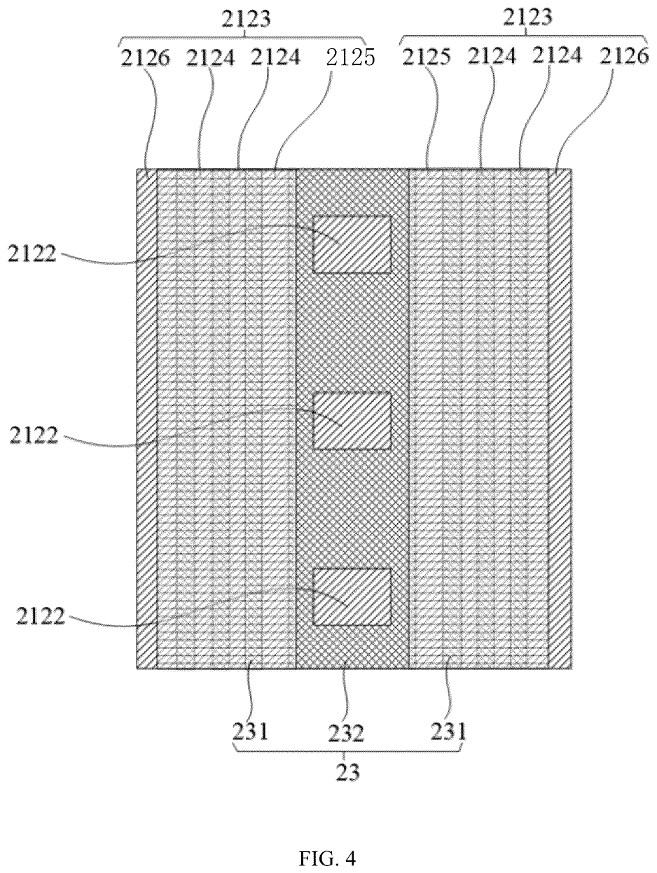

As shown in FIG. 4, the connection portion 2 further includes a first insulation layer 23. The first insulation layer 23 is arranged at a side of the first line layer 212 away from the first substrate 211. The first insulation layer 23 includes two first insulation portions 231. The two first insulation portions 231 respectively clad the first signal lines 2124 of the two first line portions 2123 and expose at least a part of the grounding structure 2121. That is, an edge of the first insulation portion 231 may be located on the surface of the plurality of grounding units 2122, or may be located between the first signal line 2124 and the plurality of grounding units 2122.

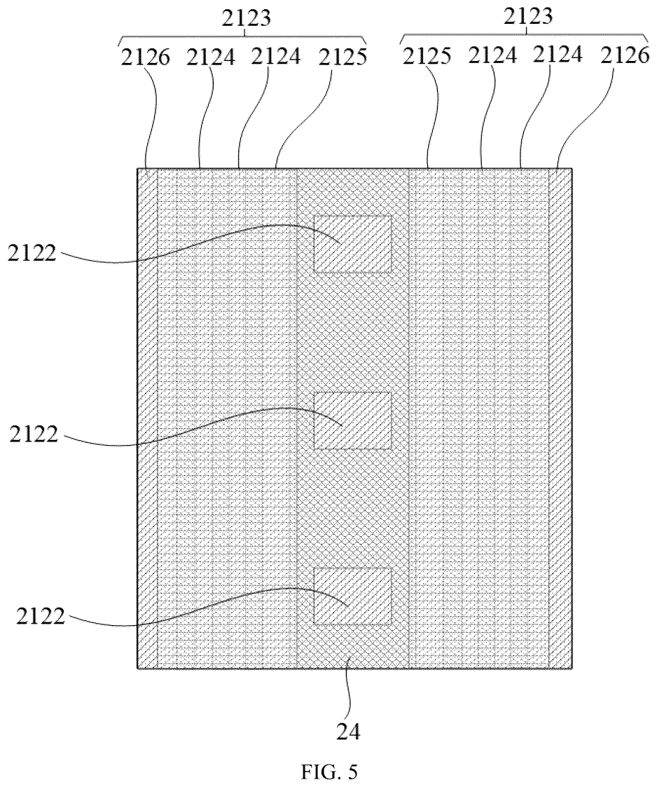

As shown in FIG. 5, the edge of the first insulation portion 231 is located between the first signal line 2124 and the plurality of grounding units 2122. The exposed region 232 is formed between the edges of the two first insulation portions 231 close to the plurality of grounding units 2122. It can be understood that the exposed region 232 is in the shape of an open opening 2321. The exposed region 232 may pass through the bend region of the connection portion 2 along the first direction, or may pass through the entire connection portion 2 along the first direction. The orthographic projections of the grounding units 2122 on the first substrate 211 are located within the orthographic projection of the exposed region 232 on the first substrate 211.

The electromagnetic shielding layer 24 is provided at a side of the first insulation layer 23 away from the first substrate 211. The electromagnetic shielding layer 24 is connected to the grounding structure 2121 through the exposed region 232. The area of the electromagnetic shielding layer 24 may be the same as the area of the first substrate 211. As shown in the figure, in order to ensure the grounding effect of the electromagnetic shielding layer 24, the edges of the two first insulation portions 231 close to the plurality of grounding units 2122 are respectively located in the gaps between the plurality of grounding units 2122 and the two first grounding sub-lines 2125.

In this way, the electromagnetic shielding layer 24 clads a surface of a grounding unit 2122 away from the first substrate 211 and side surface(s) of the grounding unit 2122, so that the electromagnetic shielding layer 24 is more tightly combined with the grounding unit 2122. It should be noted that a side surface of a grounding unit 2122 is vertically connected between a surface of the grounding unit 2122 close to the first substrate 211 and a surface of the grounding unit 2122 away from the first substrate 211.

The exposed region 232 is provided in the first insulation layer 23, and the plurality of grounding units 2122 are provided in the exposed region 232, so that the thickness of the connection portion 2 in the region where the grounding structure 2121 is located can be reduced, and the space occupied by the region where the grounding structure 2121 is located in the entire display device is reduced. During the bending procedure of the connection portion 2 of the flexible circuit board, the connection portion 2 is more easily bent in the region with a smaller thickness, thereby reducing the bending rebound force of the connection portion 2.

A part of the first insulation layer 23 on the periphery of grounding unit(s) 2122 is cut out, so that in the region where the grounding structure 2121 is located, the number of stacked layers in the periphery region of the grounding unit(s) 2122 is smaller than the number of stacked layers in the region where the grounding unit(s) 2122 is(are) located. Even if the second grounding sub-line 2126 realizes the grounding of the electromagnetic shielding layer 24, when the grounding structure 2121 is not set in the part between the two first line portions 2123, removing the first line layer 212 and the first insulation layer 23 from the periphery of the grounding unit(s) 2122 can still reduce the thickness of this region and bending rebound force of the region as compared with a case where the first insulation layer 23 covers the entire surface. The spacing between adjacent grounding units 2122 may be set to be greater than the size of a grounding unit 2122 along the first direction, which can increase the area of the region with the smallest number of stacked layers. The technical solution can further reduce the rebound force of the bendable connection portion 2 in the periphery region of the grounding unit(s) 2122.

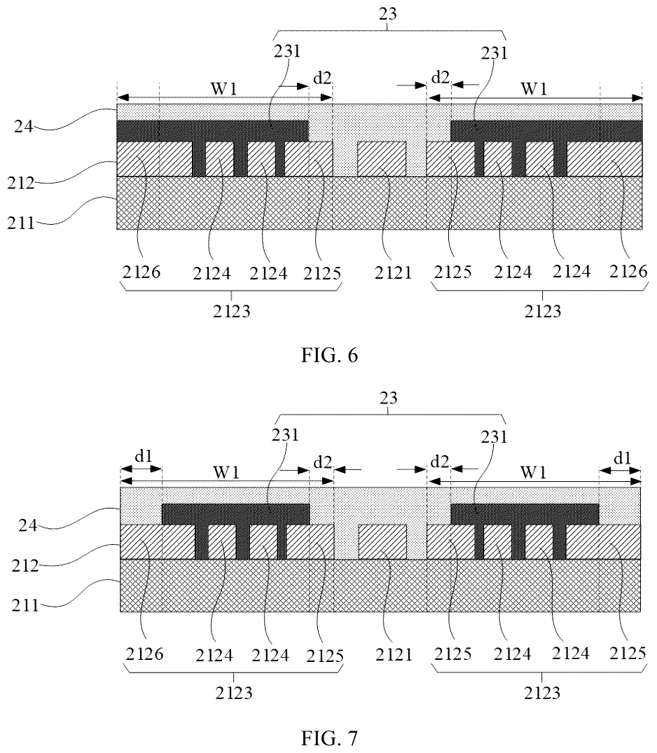

As shown in FIG. 2, FIG. 6 and FIG. 7, in order to better achieve the grounding effect of the electromagnetic shielding layer 24, the first insulation portion 231 exposes at least a part of at least one first grounding line. As shown in FIG. 6, the first insulation portion 231 may expose the first grounding sub-line 2125, and the electromagnetic shielding layer 24 is connected to the exposed part of the first grounding sub-line 2125. The width of the exposed part of the first grounding sub-line 2125 is d2. As shown in FIG. 2, the first insulation portion 231 may also expose the second grounding sub-line 2126, and the electromagnetic shielding layer 24 is connected to the exposed part of the second grounding sub-line 2126. The width of the exposed part of the second grounding sub-line 2126 is d1. As shown in FIG. 7, the first insulation portion 231 may also expose the first grounding sub-line 2125 and the second grounding sub-line 2126 at the same time, and the electromagnetic shielding layer 24 is connected to the exposed part of the first grounding sub-line 2125 and the exposed part of the second grounding sub-line 2126, so as to better ensure the grounding effect of the electromagnetic shielding layer 24. The width d2 of the exposed part of the first grounding sub-line 2125 may be equal to the width d1 of the exposed part of the second grounding sub-line 2126.

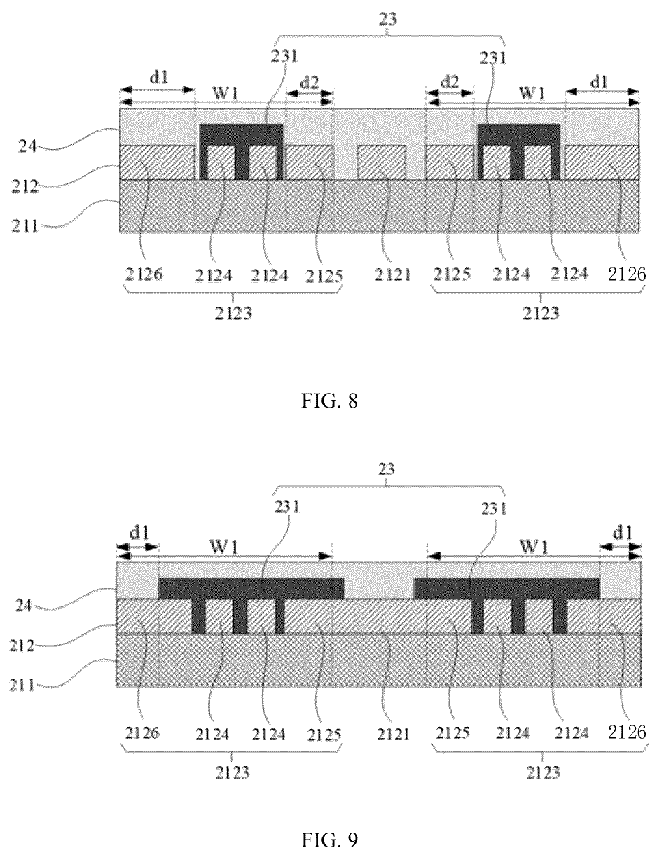

As shown in FIG. 7 and FIG. 8, the first insulation portion 231 may expose part of the first grounding line or the entire first grounding line. When the first insulation portion 231 exposes a part of the first grounding sub-line 2125, edges of the two first insulation portions 231 close to the plurality of grounding units 2122 are located between two sides of the first grounding sub-lines 2125. When the first insulation portion 231 exposes the entire first grounding sub-line 2125, d2 is the width of the first grounding sub-line 2125, and the edges of the two first insulation portions 231 close to the plurality of grounding units 2122 are located between the first grounding sub-line 2125 and the first signal line 2124. When the first insulation portion 231 exposes a part of the second grounding sub-line 2126, edges of the two first insulation portions 231 away from the plurality of grounding units 2122 are located between two sides of the second grounding sub-lines 2126. When the first insulation portion 231 exposes the entire first grounding sub-line 2126, edges of the two first insulation portions 231 away from the plurality of grounding units 2122 are located between the second grounding sub-line 2126 and the first signal line 2124, and d1 is the width of the second grounding sub-line 2126.

Since the widths of the first grounding sub-line 2125 and the second grounding sub-line 2126 are relatively small, there are process tolerances in the procedure of forming the first insulation layer 23. If the first grounding sub-line 2125 and the second grounding sub-line 2126 are directly exposed, the first signal line 2124 may be exposed, affecting signal transmission. The first insulation portion 231 exposes a part of the first grounding line, and while ensuring the grounding effect of the electromagnetic shielding layer 24, the first insulation portion 231 can completely clad the first signal line 2124, without affecting signal transmission.

In addition, the width of the first grounding sub-line 2125 and the width of the second grounding sub-line 2126 can be increased to leave a larger process tolerance range and reduce the process difficulty of forming the first insulation layer 23. However, increasing the width of the first grounding sub-line 2125 may affect the wiring of the first signal line 2124, and thus the widths of the second grounding sub-lines 2126 of two first line portions 2123 can be increased, so that the width of the second grounding sub-line 2126 is greater than the width of the first grounding sub-line 2125, the first insulation portion 231 can expose the increased part of the second grounding sub-line 2126, and reserve the grounding space for the electromagnetic shielding layer 24 on the second grounding sub-line 2126.

As shown in FIGS. 9 to 12, the difference from FIGS. 2 to 5 is that: each grounding unit 2122 is respectively connected to first grounding sub-lines 2125 on both sides, so that the plurality of grounding units 2122 and the first grounding sub-lines 2125 form a mesh structure, which increases the area of the grounding structure 2121 and can achieve a better electromagnetic grounding effect. While the two first insulation portions 231 respectively clad the first grounding sub-lines 2125 of the two first line portions 2123, the orthographic projections of the first insulation portions 231 on the first substrate 211 overlap with the orthographic projections of the plurality of grounding units 2122 on the first substrate 211.

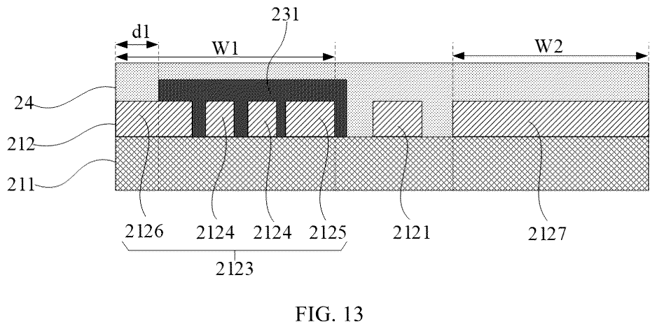

Alternatively, the connection portion 2 of the flexible circuit board may also have a signal line at a single side, as shown in FIG. 13 to FIG. 16. The grounding structure 2121 is the same as that in the above figures, including a plurality of grounding units 2122 spaced apart and arranged along the first direction. A first line portion 2123 may be arranged at a side of the grounding structure 2121. In order to avoid peeling between layers when the connection portion 2 is bent, a second line portion 2127 may be arranged at the other side of the grounding structure 2121. The width of the first line portion 2123 is equal to the width of the second line portion 2127. The distance between the first line portion 2123 and the plurality of grounding units 2122 and the distance between the second line portion 2127 and the plurality of grounding units 2122 are equal.

The first line portion 2123 includes two first signal lines 2124 and two first grounding lines. The two first grounding lines include a first grounding sub-line 2125 and a second grounding sub-line 2126. The first grounding sub-line 2125 is located between the plurality of grounding units 2122 and a first signal line 2124. The second grounding sub-line 2126 is located between a first signal line 2124 and an edge of the first substrate 211. The width of the second grounding sub-line 2126 is greater than the width of the first grounding sub-line 2125. The second line portion 2127 is a dummy grounding line and is not connected to a binding portion of the display panel.

The first insulation layer 23 includes a first insulation portion 231. The first insulation portion 231 clads the first signal line 2124 and the first grounding sub-line 2125 of the first line portion 2123. An edge of the first insulation portion 231 close to the plurality of grounding units 2122 is located between the first grounding sub-line 2125 and the plurality of grounding units 2122. An edge of the first insulation portion 231 away from the plurality of grounding units 2122 is located between two sides of the second grounding sub-line 2126. The exposed region 232 is formed between the edge of the first insulation portion 231 close to the plurality of grounding units 2122 and an edge of the first substrate 211.

The orthographic projection of the second line portion 2127 on the first substrate 211 is located within the orthographic projection of the exposed region 232 on the first substrate 211, and the orthographic projections of the grounding units 2122 on the first substrate 211 are located within the orthographic projection of the exposed region 232 on the first substrate 211. The electromagnetic shielding layer 24 is arranged at a side of the first insulation layer 23 away from the first substrate 211, and the electromagnetic shielding layer 24 is connected to the exposed part of the second grounding sub-line 2126, the plurality of grounding units 2122, and the dummy grounding line.

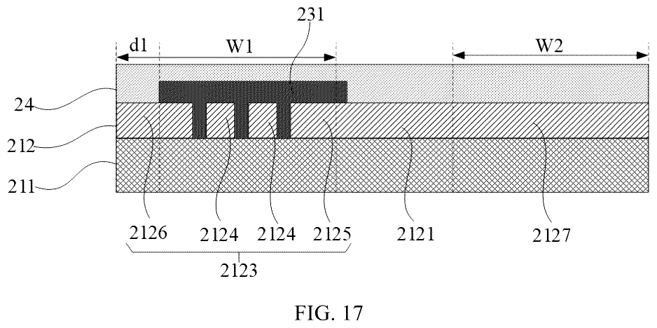

As shown in FIGS. 17 to 20, the difference from FIGS. 9 to 12 is that: each grounding unit 2122 is connected to a second line portion and a first grounding sub-line 2125, respectively, so that the plurality of grounding units 2122, the first grounding sub-lines 2125 and the second line portions form a mesh structure, which increases the area of the grounding structure 2121 and can achieve a better electromagnetic grounding effect. The edge of the first insulation portion 231 close to the plurality of grounding units 2122 is located between the first grounding sub-line 2125 and the second line portion 2127, and the orthographic projection of the first insulation portion 231 on the first substrate 211 overlaps with the orthographic projections of the plurality of grounding units 2122 on the first substrate 211. That is, the orthographic projections of the grounding units 2122 on the first substrate 211 are partially located within the orthographic projection of the exposed region 232 on the first substrate 211, and the orthographic projection of the second line portion 2127 on the first substrate 211 is located within the orthographic projection of the exposed region 232 on the first substrate 211. It can be understood that, while the first insulation portion 231 clads the first grounding sub-line 2125, a part of the first insulation portion 231 overlaps a surface of a grounding unit 2122 away from the first substrate.

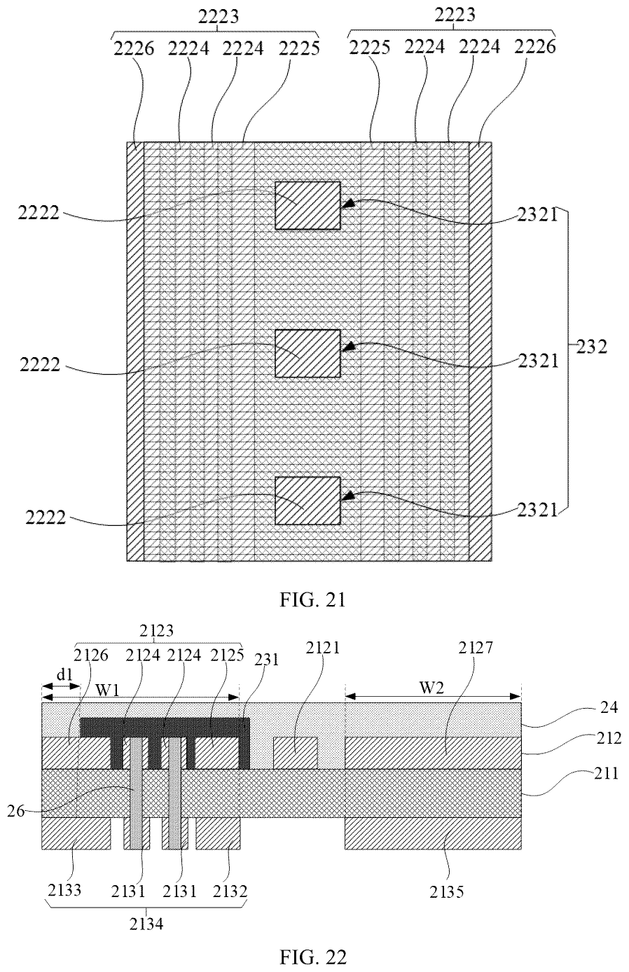

As shown in FIG. 21, in other feasible embodiments, the exposed region 232 includes a plurality of openings 2321 provided in the first insulation layer 23. The orthographic projections of the grounding units 2122 on the first substrate 211 are located within the orthographic projections of the openings 2321 on the first substrate 211. Specifically, the orthographic projection of a grounding unit 2122 on the first substrate 211 coincides with the orthographic projection of an opening 2321 on the first substrate 211. At least a part of the second grounding sub-line 2126 is exposed at two sides of the first insulation layer 23 in the second direction.

The advantage of such a configuration is that: the first insulation layer 23 is a whole layer, and there is no risk of the first signal line 2124 being exposed to the outside, and there is no need to consider process tolerances. In addition, the parts where the first insulation layer 23 overlaps with the grounding units 2122 are cut out, which can also reduce the thickness of the region where the grounding units 2122 of the connection portion are is located, thereby reducing the space occupancy in the entire display device. In addition, although the first insulation layer 23 is provided between two adjacent grounding units 2122, the bending performance of the connection portion 2 is not affected while ensuring the grounding effect of the electromagnetic shielding layer 24. The thickness of the first line layer 212 is usually smaller than that of the first insulation layer 23, and thus the bending rebound force of the connection portion 2 in this region can be reduced.

As shown in FIG. 22, when the connection portion 2 of the flexible circuit board has line(s) at a single side, the first circuit board layer group 22 further includes a second line layer 213. The second line layer 213 is arranged at a side of the first substrate 211 away from the first line layer 212. The first line layer 212 may include a second line portion 2127. The second line layer 213 may include a second signal line 2131, and the second signal line 2131 is connected to the first signal line 2124 through a first conductive structure 26 in a first via hole 291. The second signal line 2131 and the first signal line 2124 form a parallel structure to reduce the resistance during signal transmission. There may be two second signal lines 2131, and the two second signal lines 2131 are respectively connected through first conductive structures 26 in two first via holes 291.

Second grounding lines may be provided at both sides of the second signal line(s) 2131. The second grounding lines may include a third grounding sub-line 2132 and a fourth grounding sub-line 2133. The third grounding sub-line 2132 is located at a side of a second signal line 2131 close to the grounding structure 2121, and the fourth grounding sub-line 2133 is located at a side of a second signal line 2131 away from the grounding structure 2121, so as to shield the signal loaded on the second signal lines 2131. It should be noted that, because a second signal line 2131 is connected in parallel with a first signal lines 2124, the second signal line 2131 and the first signal line 2124 are loaded with the same signal.

The second signal line(s) 2131, the third grounding sub-line 2132 and the fourth grounding sub-line 2133 constitute a third grounding portion 2134. In order to ensure that the bending rebound force provided by the second line layer 213 on both sides of the grounding structure 2121 is equal, a fourth grounding portion 2135 is provided at the other side of the grounding structure 2121, and the width of the fourth grounding portion 2135 may be set equal to that of the third grounding portion 2134.

As shown in FIG. 30, for a wearable display module, the flexible circuit board also includes a second circuit board layer group 21. The second circuit board layer group 21 is arranged at a side of the first circuit board layer group 22 close to the second line layer 213. The second circuit board layer group 21 includes a second substrate 221 and a third line layer 222. The third line layer 222 is connected to the second line layer 213 through an adhesive layer 25. The third line layer 222 is arranged in most of regions of a side of the second substrate 221 away from the second line layer 213 to shield signal interference. The third line layer 222 is connected to the second line layer 213 through a second conductive structure 27 in a second via hole. The second via hole passes through the third line layer 222, the second substrate 221, the adhesive layer 25 and the second line layer 213. In addition, the flexible circuit board may also include a second insulation layer 28. The second insulation layer 28 is arranged at a side of the third line layer 222 away from the second substrate 221.

At present, when forming the first via hole 291, a first conductive layer 3 is formed on a surface of the first line layer 212, and when forming the second via hole, a second conductive layer 4 is also formed on the surface of the third line layer 222. The existence of the first conductive layer 3 and the second conductive layer 4 increases the thickness of the flexible circuit board, increases the thickness of the display module, and squeeze the space in the display device. As shown in the figure(s), the first conductive structure 26 is formed in the first via hole 291, and the second conductive structure 27 is formed in the second via hole, eliminating the first conductive layer 3 and the second conductive layer 4, thereby reducing the thickness of the flexible circuit board.

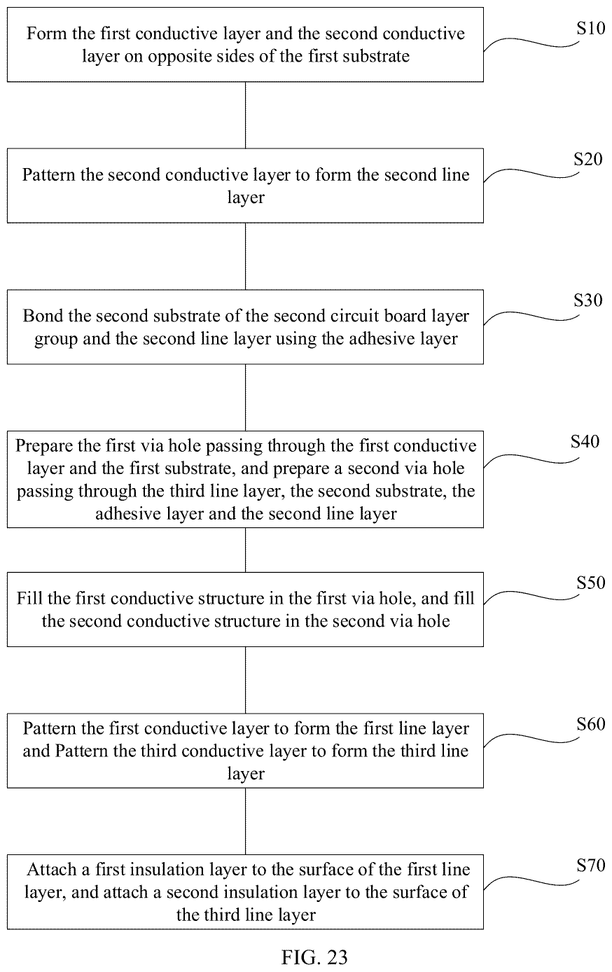

The following describes the manufacturing procedure of the flexible circuit board involved in an embodiment of the present disclosure. As shown in FIG. 23, the manufacturing procedure of the flexible circuit board may include:

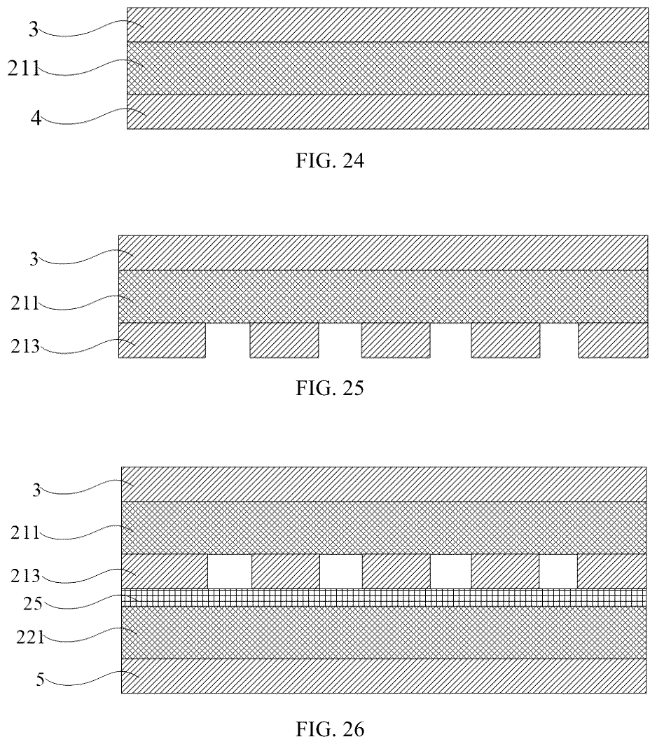

In step S10, the first conductive layer 3 and the second conductive layer 4 are formed on opposite sides of the first substrate 211, as shown in FIG. 24.

In step S20, the second conductive layer 4 is patterned to form the second line layer 213, as shown in FIG. 25.

In step S30, the second substrate 221 of the second circuit board layer group 21 and the second line layer 213 are bonded together using the adhesive layer 25, as shown in FIG. 26.

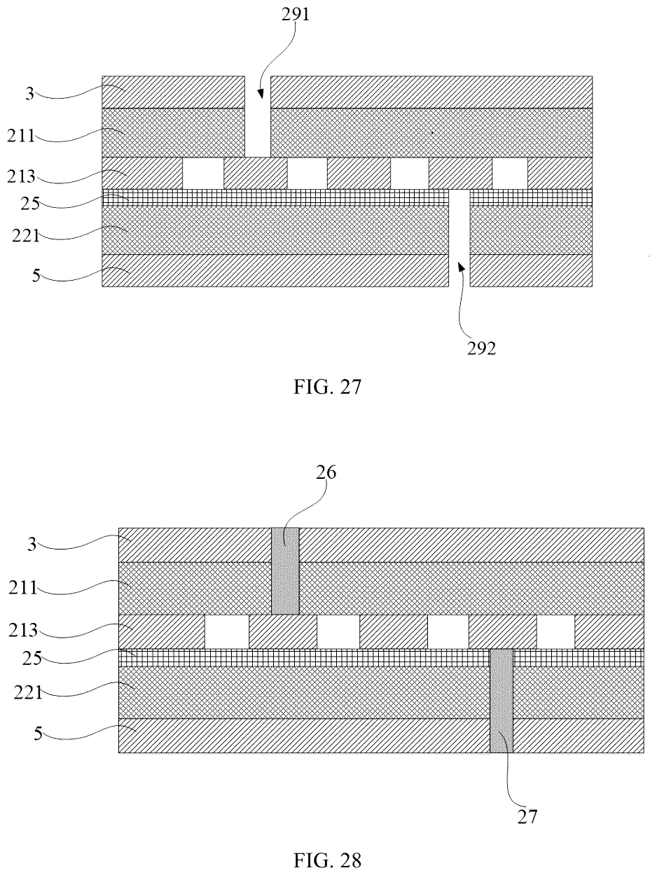

In step S40, the first via hole 291 passing through the first conductive layer 3 and the first substrate 211 is prepared, and a second via hole passing through the third line layer 222, the second substrate 221, the adhesive layer 25 and the second line layer 213 is prepared, as shown in FIG. 27.

In step S50, the first conductive structure 26 is filled in the first via hole 291, and the second conductive structure 27 is filled in the second via hole, as shown in FIG. 28.

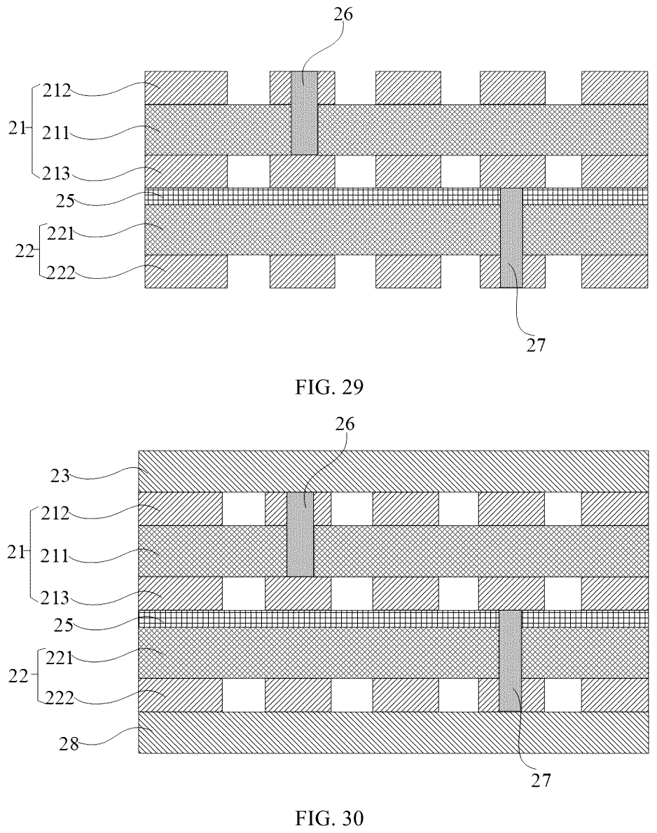

In step S60, the first conductive layer 3 is patterned to form the first line layer 212, and the third conductive layer 5 is patterned to form the third line layer 222, as shown in FIG. 29.

In step S70, a first insulation layer 23 is attached to the surface of the first line layer 212, and a second insulation layer 28 is attached to the surface of the third line layer 222, as shown in FIG. 30.

An implementation of the present disclosure also provides a display module. The display module may include the display panel involved in any one of the above implementations of the present disclosure. The main body 1 of the flexible circuit board is usually attached to a non-display surface of the display panel, and the connection portion 2 is bent from a side of the display panel to a display surface of the display panel and is bound to the display panel.

An implementation of the present disclosure also provides a display device. The display device may include the display module involved in the above implementation of the present disclosure. The specific structure and beneficial effects of the display module have been described in detail above, and thus repeated descriptions will be omitted here.

It should be noted that, in addition to the display module, the display device also includes other necessary parts and components, such as a housing, a power line, etc. Those skilled in the art may make corresponding supplements according to the specific use requirements of the display device, which will not be elaborated here.

When the flexible circuit board is of the structure(s) shown in the figures, the display device may be a traditional electronic device, such as a mobile phone, a computer, a television, and a camcorder, or it may be an emerging wearable device, such as a virtual reality device and an augmented reality device, which are not listed here one by one.

According to an aspect of the present disclosure, there is provided a flexible circuit board, including a connection portion extending along a first direction. The connection portion includes: a first circuit board layer group, a first insulation layer and an electromagnetic shielding layer. The first circuit board layer group includes a first substrate and a first line layer. The first line layer is arranged at a side of the first substrate, the first line layer includes a plurality of grounding units spaced apart and arranged along the first direction, a first line portion is arranged at a side of the plurality of grounding units, and the first line portion includes a first grounding line. The first insulation layer is arranged at a side of the first line layer away from the first substrate. The first insulation layer is provided with an exposed region, an orthographic projection of the exposed region on the first substrate overlaps with orthographic projections of the grounding units on the first substrate, and the first insulation layer exposes at least a part of the first grounding line. The electromagnetic shielding layer is arranged at a side of the first insulation layer away from the first substrate, wherein the electromagnetic shielding layer is connected to the grounding units through the exposed region and is connected to an exposed part of the first grounding line.

In an embodiment of the present disclosure, the first line portion is provided at a side of the plurality of grounding units, and a first line portion or a second line portion is provided at the other side of the plurality of grounding units, the first line portion is used for binding with a display panel, the second line portion is a dummy grounding line, and a width of the first line portion is equal to a width of the second line portion.

In an embodiment of the present disclosure, the first line portion includes a first signal line and at least two first grounding lines, the at least two first grounding lines are respectively arranged at both sides of the first signal line, and the first insulation layer clads the first signal line and exposes at least a part of at least one of the first grounding lines.

In an embodiment of the present disclosure, the at least two first grounding lines include a first grounding sub-line and a second grounding sub-line, the first grounding sub-line is located between the plurality of grounding units and the first signal line, the second grounding sub-line is located between the first signal line and an edge of the first substrate, and the first insulation layer exposes at least a part of the second grounding sub-line.

In an embodiment of the present disclosure, a width of the second grounding sub-line is greater than a width of the first grounding sub-line.

In an embodiment of the present disclosure, first line portions are respectively provided at both sides of the plurality of grounding units, the first insulation layer includes two first insulation portions, the two first insulation portions respectively clad first signal lines and first grounding sub-lines of the two first line portions, and the exposed region is between edges of the two first insulation portions close to the plurality of grounding units.

In an embodiment of the present disclosure, two first line portions are arranged as spaced apart from the plurality of grounding units, the edges of the two first insulation portions close to the plurality of grounding units are respectively located between gaps between the plurality of grounding units and the two first line portions, and the orthographic projections of the grounding units on the first substrate are located within an orthographic projection of the exposed region on the first substrate.

In an embodiment of the present disclosure, the first line portion is provided at a side of the plurality of grounding units, and the second line portion is provided at the other side of the plurality of grounding units, the first insulation layer includes a first insulation portion, the first insulation portion clads the first signal line and the first grounding sub-line of the first line portion, and the exposed region is between an edge of the first insulation portion close to the plurality of grounding units and an edge of the first substrate.

In an embodiment of the present disclosure, the second line portion and the first line portion are arranged as respectively spaced apart from the plurality of grounding units, the edge of the first insulation portion close to the plurality of grounding units is located between a gap between the plurality of grounding units and the first line portion, and the orthographic projections of the grounding units on the first substrate and an orthographic projection of the second line portion on the first substrate are located within an orthographic projection of the exposed region on the first substrate.

In an embodiment of the present disclosure, each of the grounding units is connected to the first grounding sub-lines on both sides respectively, and orthographic projections of two first insulation portions on the first substrate overlap with the orthographic projections of the plurality of grounding units on the first substrate.

In an embodiment of the present disclosure, each of the grounding units is connected to the second line portion and the first grounding sub-line respectively, the edge of the first insulation portion close to the plurality of grounding units is located between the first grounding sub-line and the second line portion, and an orthographic projection of the first insulation portion on the first substrate overlaps with the orthographic projections of the plurality of grounding units on the first substrate.

In an embodiment of the present disclosure, the exposed region includes a plurality of openings provided in the first insulation layer, and the orthographic projections of the grounding units on the first substrate are located within orthographic projections of the openings on the first substrate.

In an embodiment of the present disclosure, distances between two first line portions and the plurality of grounding units are equal.

In an embodiment of the present disclosure, a distance between the first line portion and the plurality of grounding units is equal to a distance between the second line portion and the plurality of grounding units.

In an embodiment of the present disclosure, there are a plurality of signal lines, and a distance between two adjacent signal lines, a distance between the first grounding sub-line and an adjacent first signal line, and a distance between the second grounding sub-line and an adjacent first signal line are equal.

In an embodiment of the present disclosure, the first circuit board layer group further includes a second line layer, the second line layer is arranged at a side of the first substrate away from the first line layer, the second line layer is connected to the first line layer through a first conductive structure in a first via hole, and the first via hole passes through the first line layer and the first substrate.

In an embodiment of the present disclosure, the second line layer includes a second line portion, the second line portion includes a second signal line, and the second signal line is connected to the first signal line through the first conductive structure in the first via hole.

In an embodiment of the present disclosure, the flexible circuit board further includes a second circuit board layer group, the second circuit board layer group is arranged at a side of the first circuit board layer group close to the second line layer, the second circuit board layer group includes a second substrate and a third line layer, the second substrate is connected to the second line layer through an adhesive layer, the third line layer is arranged at a side of the second substrate away from the second line layer, the third line layer is connected to the second line layer through a second conductive structure in a second via hole, and the second via hole passes through the third line layer, the second substrate, the adhesive layer and the second line layer.

In an embodiment of the present disclosure, the flexible circuit board further includes a second insulation layer, and the second insulation layer is arranged at a side of the third line layer away from the second substrate.

According to another aspect of the present disclosure, there is provided a display module. The display module includes the flexible circuit board provided in an aspect of the present disclosure.

According to a further aspect of the present disclosure, there is provided a display device. The display device includes the display module provided in an aspect of the present disclosure.

The flexible circuit board in the present disclosure includes the connection portion, and the connection portion includes the first line layer, the first insulation layer and the electromagnetic shielding layer which are stacked. The first line layer includes a plurality of grounding units which are arranged as spaced apart. In the first line layer, the parts between the grounding units are cut out, thus reducing the thickness of the connection portion in this region and reducing the bending rebound force of the connection portion. The first insulation layer is provided with the exposed region, and the orthographic projection of the exposed region on the first substrate overlaps with the orthographic projections of the grounding units on the first substrate. The electromagnetic shielding layer is connected to the grounding units through the exposed region. The first insulation layer exposes at least a part of at least one first grounding line, and the electromagnetic shielding layer is connected to the exposed part of the first grounding line. The grounding units and the first grounding line can ensure the grounding effect of the electromagnetic shielding layer. Therefore, the flexible circuit board can take into account the bending performance of the neck region while ensuring the grounding effect of the electromagnetic shielding layer of the connection portion.

Those skilled in the art will readily appreciate other implementations of the present disclosure after considering the description and practicing the invention disclosed herein. This application is intended to cover any modification, use or adaptation of the present disclosure, which follows the general principles of the present disclosure and includes common knowledge or customary means in the art that are not disclosed in the present disclosure. The description and embodiments are intended to be illustrative only, and the true scope and spirit of the present disclosure are indicated by the appended claims.

1. A flexible circuit board, comprising a connection portion extending along a first direction, wherein the connection portion comprises:
a first circuit board layer group comprising a first substrate and a first line layer, wherein the first line layer is arranged at a side of the first substrate, the first line layer comprises a plurality of grounding units spaced apart and arranged along the first direction, a first line portion is arranged at a side of the plurality of grounding units, and the first line portion comprises at least one first grounding line;
a first insulation layer arranged at a side of the first line layer away from the first substrate, wherein the first insulation layer comprises an exposed region, an orthographic projection of the exposed region on the first substrate overlaps with orthographic projections of the grounding units on the first substrate, and the first insulation layer exposes at least a part of the at least one first grounding line; and
an electromagnetic shielding layer arranged at a side of the first insulation layer away from the first substrate, wherein the electromagnetic shielding layer is connected to the grounding units through the exposed region and is connected to an exposed part of the at least one first grounding line.

2. The flexible circuit board according to claim 1, wherein the first line portion is provided at a side of the plurality of grounding units, and a first line portion or a second line portion is provided at the other side of the plurality of grounding units, the first line portion is used for binding with a display panel, the second line portion is a dummy grounding line, and a width of the first line portion is equal to a width of the second line portion.

3. The flexible circuit board according to claim 2, wherein the at least one first grounding line comprises at least two first grounding lines;
wherein the first line portion provided at the side of the plurality of grounding units comprises at least one first signal line and the at least two first grounding lines, the at least two first grounding lines are respectively arranged at both sides of the at least one first signal line, and the first insulation layer at least clads the at least one first signal line and exposes at least a part of at least one of the first grounding lines.

4. The flexible circuit board according to claim 3, wherein the at least two first grounding lines comprise a first grounding sub-line and a second grounding sub-line, the first grounding sub-line is located between the plurality of grounding units and the at least one first signal line, the second grounding sub-line is located between the at least one first signal line and an edge of the first substrate, and the first insulation layer exposes at least a part of the second grounding sub-line.

5. The flexible circuit board according to claim 4, wherein a width of the second grounding sub-line is greater than a width of the first grounding sub-line.

6. The flexible circuit board according to claim 4, wherein first line portions are respectively provided at both sides of the plurality of grounding units, the first insulation layer comprises two first insulation portions, the two first insulation portions respectively clad first signal lines and first grounding sub-lines of the two first line portions, and a region between edges of the two first insulation portions close to the plurality of grounding units is the exposed region.

7. The flexible circuit board according to claim 6, wherein two first line portions are arranged as spaced apart from the plurality of grounding units, the edges of the two first insulation portions close to the plurality of grounding units are respectively located in gaps between the plurality of grounding units and the two first line portions, and the orthographic projections of the grounding units on the first substrate are located within an orthographic projection of the exposed region on the first substrate.

8. The flexible circuit board according to claim 4, wherein the first line portion is provided at a side of the plurality of grounding units, and the second line portion is provided at the other side of the plurality of grounding units, the first insulation layer comprises a first insulation portion, the first insulation portion clads the at least one first signal line and the first grounding sub-line of the first line portion, and a region between an edge of the first insulation portion close to the plurality of grounding units and an edge of the first substrate is the exposed region.

9. The flexible circuit board according to claim 8, wherein the second line portion and the first line portion are arranged as respectively spaced apart from the plurality of grounding units, the edge of the first insulation portion close to the plurality of grounding units is located in a gap between the plurality of grounding units and the first line portion, and the orthographic projections of the grounding units on the first substrate and an orthographic projection of the second line portion on the first substrate are located within an orthographic projection of the exposed region on the first substrate.

10. The flexible circuit board according to claim 6, wherein each of the grounding units is connected to the first grounding sub-lines on both sides respectively, and orthographic projections of two first insulation portions on the first substrate overlap with the orthographic projections of the plurality of grounding units on the first substrate.

11. The flexible circuit board according to claim 8, wherein each of the grounding units is connected to the second line portion and the first grounding sub-line respectively, the edge of the first insulation portion close to the plurality of grounding units is located between the first grounding sub-line and the second line portion, and an orthographic projection of the first insulation portion on the first substrate overlaps with the orthographic projections of the plurality of grounding units on the first substrate.

12. The flexible circuit board according to claim 4, wherein the exposed region comprises a plurality of openings provided in the first insulation layer, and the orthographic projections of the grounding units on the first substrate are located within orthographic projections of the openings on the first substrate.

13. The flexible circuit board according to claim 6, wherein distances between two first line portions and the plurality of grounding units are equal.

14. The flexible circuit board according to claim 8, wherein a distance between the first line portion and the plurality of grounding units is equal to a distance between the second line portion and the plurality of grounding units.

15. The flexible circuit board according to claim 4, wherein the at least one first signal line comprises a plurality of first signal lines, and a distance between two adjacent first signal lines, a distance between the first grounding sub-line and an adjacent first signal line, and a distance between the second grounding sub-line and an adjacent first signal line are equal.

16. The flexible circuit board according to claim 3, wherein the first circuit board layer group further comprises a second line layer, the second line layer is arranged at a side of the first substrate away from the first line layer, the second line layer is connected to the first line layer through a first conductive structure in a first via hole, and the first via hole passes through the first line layer and the first substrate.

17. The flexible circuit board according to claim 16, wherein the second line layer comprises a second line portion, the second line portion comprises a second signal line, and the second signal line is connected to the first signal line through the first conductive structure in the first via hole.

18. The flexible circuit board according to claim 16, wherein the flexible circuit board further comprises a second circuit board layer group, the second circuit board layer group is arranged at a side of the first circuit board layer group close to the second line layer, the second circuit board layer group comprises a second substrate and a third line layer, the second substrate is connected to the second line layer through an adhesive layer, the third line layer is arranged at a side of the second substrate away from the second line layer, the third line layer is connected to the second line layer through a second conductive structure in a second via hole, and the second via hole passes through the third line layer, the second substrate, the adhesive layer and the second line layer.

19. The flexible circuit board according to claim 18, wherein the flexible circuit board further comprises a second insulation layer, and the second insulation layer is arranged at a side of the third line layer away from the second substrate.

20. A display module, comprising a flexible circuit board;
wherein flexible circuit board comprises a connection portion extending along a first direction, wherein the connection portion comprises:
a first circuit board layer group comprising a first substrate and a first line layer, wherein the first line layer is arranged at a side of the first substrate, the first line layer comprises a plurality of grounding units spaced apart and arranged along the first direction, a first line portion is arranged at a side of the plurality of grounding units, and the first line portion comprises at least one first grounding line;
a first insulation layer arranged at a side of the first line layer away from the first substrate, wherein the first insulation layer comprises an exposed region, an orthographic projection of the exposed region on the first substrate overlaps with orthographic projections of the grounding units on the first substrate, and the first insulation layer exposes at least a part of the at least one first grounding line; and
an electromagnetic shielding layer arranged at a side of the first insulation layer away from the first substrate, wherein the electromagnetic shielding layer is connected to the grounding units through the exposed region and is connected to an exposed part of the at least one first grounding line.

21. (canceled)
